(19) United States
(12) Patent Application Publication
(10) Pub. No.: US 2026/0200724 A1
(43) Pub. Date: Jul. 16, 2026

(54) MICROMECHANICAL COMPONENT FOR A CAPACITIVE SENSOR AND/OR ACTUATOR DEVICE

(71) Applicant: Robert Bosch GmbH, Stuttgart (DE)

(72) Inventors: Christoph Schelling, Stuttgart (DE); Maximilian Sommer, Dresden (DE); Volkmar Senz, Metzingen (DE)

(21) Appl. No.: 19/437,758

(22) Filed: Dec. 31, 2025

(30) Foreign Application Priority Data
Jan. 16, 2025 (DE) 10 2025 101 446.9

(51) Int. Cl. B81B 3/00; B81C 1/00

(52) U.S. Cl. CPC B81B 3/0078; B81C 1/00666; B81B 2201/0257; B81B 2201/0264; B81B 2203/0127; B81B 2203/0307; B81B 2203/04

(57) ABSTRACT

A micromechanical component for a capacitive sensor and/or actuator device. The micromechanical component including a deformable first membrane and a deformable second membrane, wherein an internal volume is bounded by a first membrane surface of the first membrane and a second membrane surface of the second membrane, and at least one first electrode arranged in the internal volume, which includes continuous recesses, in each case in the form of a slot extending along a straight or non-straight slot center longitudinal line, which recesses are configured such that a straight line that can be defined for the particular slot and passes through a first endpoint and through a second endpoint of its slot center longitudinal line extends radially away from a center point of the first electrode or perpendicularly away from a central axis of the first electrode with a deviation of less than or equal to 20°.

### CROSS REFERENCE

The present application claims the benefit under 35 U.S.C. § 119 of Germany Patent Application No. DE 10 2025 101 446.9 filed on January 6, 2025, which is expressly incorporated herein by reference in its entirety.

### FIELD

The present invention relates to a micromechanical component for a capacitive sensor and/or actuator device. The present invention also relates to a capacitive sensor and/or actuator device. Furthermore, the present invention relates to a production method for a micromechanical component for a capacitive sensor and/or actuator device.

### BACKGROUND INFORMATION

In the related art, such as U.S. Patent Nos. US 9,986,344 B2 and US 9,181,080 B2, MEMS microphones are described which in each case are equipped with a deformable first membrane, a deformable second membrane and a counter electrode arranged between the membranes. The first membrane and the second membrane are connected to one another by first pillars and second pillars, wherein each of the first pillars has a greater extent in a first spatial direction aligned parallel to the first membrane and the second membrane than in a second spatial direction aligned parallel to the first membrane and the second membrane and perpendicular to the first spatial direction, while each of the second pillars has a smaller extent in the first spatial direction than in the second spatial direction. The first and second pillars in each case extend through holes in the counter electrode, wherein a particular shape of the holes is adapted to the shape of the associated first or second pillar.

### SUMMARY

The present invention provides a micromechanical component for a capacitive sensor and/or actuator device, a capacitive sensor and/or actuator device and a production method for a micromechanical component for a capacitive sensor and/or actuator device.

The present invention provides micromechanical components that, when used in a capacitive sensor and/or actuator device, lead to an increased signal-to-noise ratio of the particular capacitive sensor and/or actuator device, or to an improved noise performance of the particular capacitive sensor and/or actuator device. This advantage is ensured by means of the present invention in that the micromechanical component according to the invention comprises at least one first electrode with a perforation optimized for a molecular damping regime. The optimized perforation is realized through an improved slot design of the/all slot(s) in the first electrode compared to the related art. Due to the improved slot design of the/all slot(s) in the first electrode, damping that occurs during operation of the micromechanical component according to the invention is reduced and, at the same time, a tensile stress in the first electrode that is advantageous for sensitivity is maintained. The micromechanical component according to the invention can therefore be built smaller with the same performance or more powerful with the same component size compared to the prior art described above. The present invention thus also contributes to the miniaturization of capacitive sensor and/or actuator devices. Accordingly, the present invention can also be used to save energy during operation of capacitive sensor and/or actuator devices.

The present invention in particular allows for a flow or damping of residual gases at the first electrode such that noise is limited. Surprisingly, it has been shown that, at a comparable degree of perforation in the molecular flow regime at gas pressures below 10 mbar, an additional pillar-independent, slot-shaped perforation arrangement of at least one of the capacitive plates of the sensor and/or actuator device allows for significantly lower damping than perforation arrangements having a non-elongated cross-section.

In an advantageous embodiment of the micromechanical component of the present invention, the slots in the first electrode are configured such that the straight lines passing through the first endpoint of the slot center longitudinal line of the particular slot and through the second endpoint of the slot center longitudinal line of the same slot extend radially away from the center point of the first electrode with a deviation of less than or equal to 20°, wherein each first endpoint of the slot center longitudinal lines of the slots is closer to the center point of the first electrode than the second endpoint of the slot center longitudinal line of the same slot, and wherein, as the slots, at least first slots and second slots in the first electrode are configured such that the first endpoints of the slot center longitudinal lines of the first slots lie on a first circular path having a first radius about the center point of the first electrode, and the first endpoints of the slot center longitudinal lines of the second slots lie on a second circular path having a second radius, greater than the first radius, about the center point of the first electrode. In the embodiment of the micromechanical component described here, the first electrode thus comprises at least a two-ring configuration of slots, which is advantageous for reduced gas damping at the first electrode. The number of slots can be different in each ring, and the ring regions can partially overlap radially.

In particular, the first slots can have an equal first maximum slot length radially away from the center point of the first electrode and an equal first maximum slot width perpendicular to their first maximum slot length, and the second slots can have an equal second maximum slot length radially away from the center point of the first electrode and an equal second maximum slot width perpendicular to their second maximum slot length, wherein the first maximum slot length can differ from the second maximum slot length and/or the first maximum slot width can differ from the second maximum slot width. Such alternating maximum slot lengths and/or maximum slot widths of the first slots and the second slots contribute to an additional reduction of the damping occurring during operation of the capacitive sensor and/or actuator device equipped with the embodiment of the micromechanical component described here.

In one further advantageous embodiment of the micromechanical component of the present invention, the slots in the first electrode are configured such that the straight lines passing through the first endpoint of the slot center longitudinal line of the particular slot and through the second endpoint of the slot center longitudinal line of the same slot extend perpendicularly away from the central axis of the first electrode with a deviation of less than or equal to 20°, wherein each first endpoint of the slot center longitudinal lines of the slots lies closer to the central axis of the first electrode than the second endpoint of the slot center longitudinal line of the same slot, and wherein, as the slots, at least first slots and second slots in the first electrode are configured such that the first endpoints of the slot center longitudinal lines of the first slots lie on two straight lines running parallel to the central axis of the first electrode at an equal first spacing from the central axis of the first electrode, and the first endpoints of the slot center longitudinal lines of the second slots lie on two further straight lines running parallel to the central axis of the first electrode at an equal second spacing, greater than the first spacing, to the central axis of the first electrode. The slot design described here realizes at least a two-parallel strip configuration of the slots configured in the first electrode, which configuration ensures reduced damping of the micromechanical component realized in this way.

Preferably, according to an example embodiment of the present invention, the first slots have an equal first maximum slot length perpendicular to the central axis of the first electrode and an equal first maximum slot width parallel to the central axis of the first electrode, and the second slots have an equal second maximum slot length perpendicular to the central axis of the first electrode and an equal second maximum slot width parallel to the central axis of the first electrode, wherein the first maximum slot length can differ from the second maximum slot length and/or the first maximum slot width can differ from the second maximum slot width. Even with a slot design of the slots configured in the first electrode with at least a two-parallel strip configuration, damping occurring during operation of the embodiment of the micromechanical component described here can be reduced by different maximum slot lengths and/or slot widths.

Preferably, at least some of the slots are trapezoidal, meandering and/or S-shaped. By deviating the shape of at least some of the slots in the first electrode from the conventional "rectangular shape," the damping of a micromechanical component realized in this way, or of the capacitive sensor and/or actuator device equipped with it, can be further improved.

Advantageously, the first membrane can be mechanically connected to the second membrane via support elements, wherein the support elements in each case are mechanically coupled to the first membrane surface and to the second membrane surface, and wherein at least two of the support elements extend through the same slot in the first electrode. In particular, at least two of the support elements can extend through the same slot in the first electrode without touching one another. The slot can be widened in the immediate vicinity of the support elements. This can help improve the deformability of the first membrane and the second membrane and minimize any loss of capacitive area that would otherwise occur due to separate through-holes for support elements elsewhere.

Advantageously, a particular spacing between two adjacent slots of the first electrode can lie in a range of values between 2 µm and 12 µm. The slot width can be between 200 nm and 2 µm, in particular 0.5 µm; a slot length can be between 5 µm and 500 µm, in particular 25 µm. This improves the flow behavior of air or gas flows occurring during operation of the capacitive sensor and/or actuator device equipped with the embodiment of the micromechanical component described here, which significantly reduces the damping occurring during operation.

Advantageously, in an elliptical or circular embodiment with a plurality of rings of slots, the particular angular spacing of the straight lines of two adjacent slots can be 15° in a radially inner region and 0.5° in an outer region. This improves the flow behavior of air or gas flows occurring during operation of the capacitive sensor and/or actuator device equipped with the embodiment of the micromechanical component described here, which significantly reduces the damping occurring during operation.

As an advantageous development of the present invention, an electrode system that comprises not only the first electrode but also at least one second electrode can be arranged in the internal volume, wherein either the first electrode or the at least one second electrode is fixed to the holder in such a way that a spacing of the first electrode from the particular second electrode can be varied by means of a non-zero potential difference applied in each case between the first electrode and the at least one second electrode.

If applicable, it is preferred if the at least one second electrode also comprises continuous recesses, in each case in the form of a slot extending along a straight or non-straight slot center longitudinal line, wherein the slots in the particular second electrode are configured such that a straight line that can be defined for the particular slot and passes through a first endpoint of its slot center longitudinal line lying on an edge of the particular slot and through a second endpoint of its slot center longitudinal line lying on the edge of the particular slot extends radially away from a center point of the second electrode with a deviation of less than or equal to 20° or extends perpendicularly away from a central axis of the second electrode, which intersects the particular second electrode at its center, with a deviation of less than or equal to 20°, and wherein the slots in the at least one second electrode are configured with an offset in relation to the slots in the first electrode. The at least one second electrode can thus also be configured in a damping-reducing manner.

In particular, the slots in the first electrode can be configured such that the straight line passing through the first endpoint of the slot center longitudinal line of the particular slot and through the second endpoint of the slot center longitudinal line of the same slot extends radially away from the center point of the first electrode with a deviation of less than or equal to 10° or perpendicularly away from the central axis of the first electrode with a deviation of less than or equal to 10°. Specifically, the slots in the first electrode can be configured such that the straight line passing through the first endpoint of the slot center longitudinal line of the particular slot and through the second endpoint of the slot center longitudinal line of the same slot extends radially away from the center point of the first electrode with a deviation of less than or equal to 5° or perpendicularly away from the central axis of the first electrode with a deviation of less than or equal to 5°.

Preferably, the first electrode is anchored to the holder by means of at least two anchor structures in such a way that an anchor-structure line that can be defined for the particular anchor structure and passes through a first endpoint of the particular anchor structure anchored to the first electrode and through a second endpoint of the particular anchor structure anchored to the holder can be mapped by rotation or translation onto each straight line that can be defined for at least one of the slots of the first electrode. The anchoring of the first electrode to the holder described here maintains advantageous mechanical tensile stresses over the length of the first electrode.

The advantages described above are also realized in a capacitive sensor and/or actuator device with a micromechanical component according to the present invention.

Furthermore, the advantages described above can also be achieved by carrying out a suitable production method for a micromechanical component for a capacitive sensor and/or actuator device according to the present invention. It is expressly pointed out that the production method can be developed in accordance with the embodiments of the micromechanical component of the present invention explained above.

### BRIEF DESCRIPTION OF THE DRAWINGS

Further features and advantages of the present invention are explained in the following with reference to the figures.

FIG. 1A to 1D are schematic overall and partial representations of a first example embodiment of the micromechanical component according to the present invention and a coordinate system to explain its function.

FIG. 2A and 2B are schematic partial representations of a second example embodiment of the micromechanical component according to the present invention.

FIG. 3 is a schematic partial representation of a third example embodiment of the micromechanical component of the present invention.

FIG. 4A and 4B are schematic partial representations of a fourth example embodiment of the micromechanical component of the present invention.

FIG. 5 to 9 are schematic partial representations of further example embodiments of the micromechanical component of the present invention.

FIG. 10 is a flowchart to explain one example embodiment of the production method for a micromechanical component for a capacitive sensor and/or actuator device, according to the present invention.

### DETAILED DESCRIPTION OF EXAMPLE EMBODIMENTS

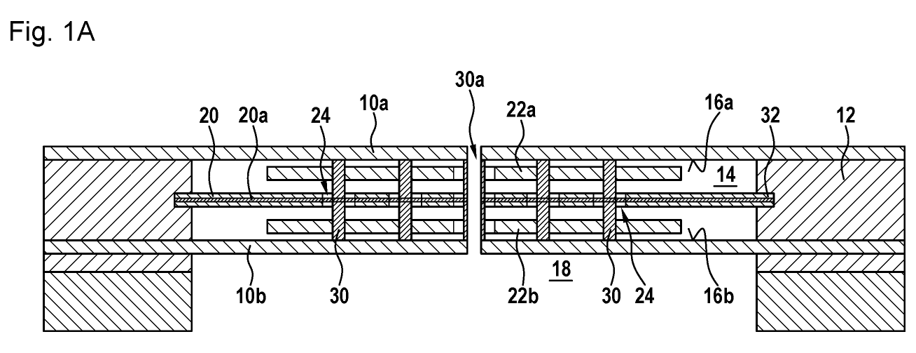

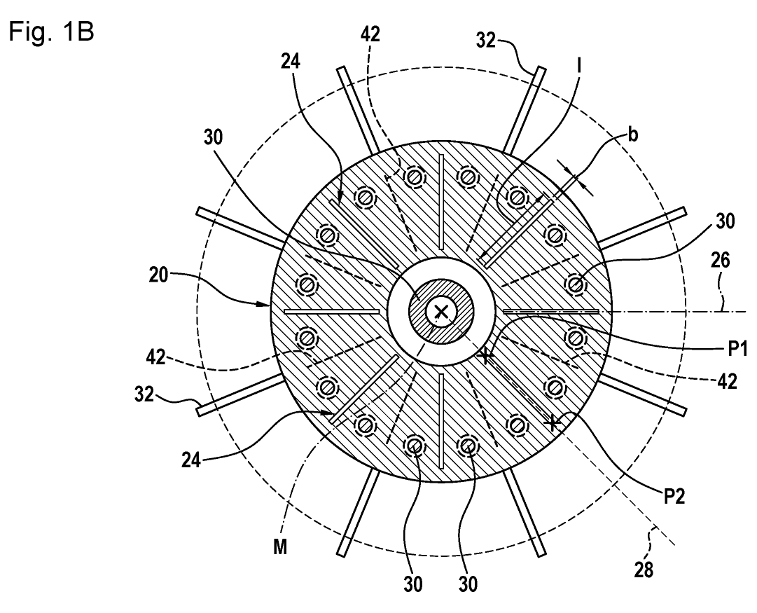

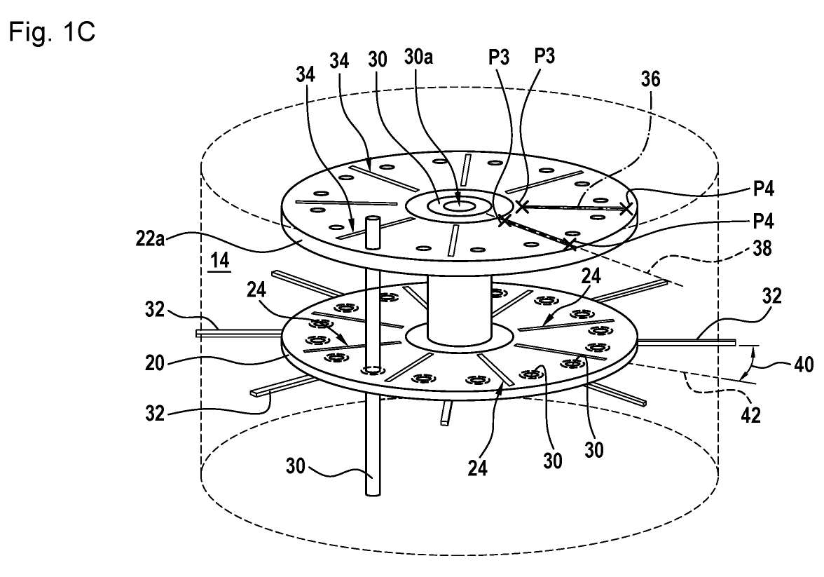

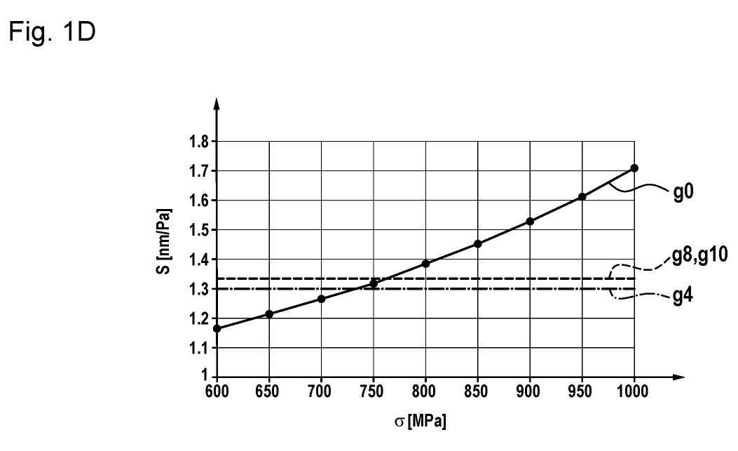

FIG. 1A to 1D are schematic overall and partial representations of a first embodiment of the micromechanical component and a coordinate system to explain its function.

The micromechanical component shown schematically in FIG. 1A to 1C comprises a first membrane 10a and a second membrane 10b, which are tensioned on and/or in a holder 12 of the micromechanical component in such a way that an internal volume 14 is bounded by means of the membranes 10a and 10b. For this purpose, the internal volume 14 is bounded on its first side by a first membrane surface 16a of the first membrane 10a and on its second side, which is directed away from the first side, by a second membrane surface 16b of the second membrane 10b. In particular, the internal volume 14 can be sealed in an air-tight or gas-tight manner against an external environment of the micromechanical component by means of the membranes 10a and 10b and the holder 12. The first membrane 10a and the second membrane 10b in each case are to be understood to mean a membrane 10a and 10b that is deformable by means of a force acting upon it. The membranes 10a and 10b can, in particular, at least partially span a rear side cavity 18 configured in the holder 12.

At least one first electrode 20 is arranged in the internal volume 14. Preferably, a fluid pressure of less than or equal to 10 mbar prevails in the internal volume 14 so that fluidic flow processes caused by relative movement of the membranes 10a and 10b in relation to the first electrode 20 are in a molecular flow regime. Optionally, the first electrode 20 can be configured with an insulating layer 20a extending (substantially) centrally through the first electrode 20. Alternatively, the first electrode 20 can also be made entirely of an electrically conductive material. Advantageously, the first electrode 20 is under a tensile stress so that it yields as little as possible to a force acting perpendicularly on it, which force is caused, e.g., by a pressure difference between the two sides of the first electrode 20.

As an advantageous development, the micromechanical component of FIG. 1A and 1B comprises in its internal volume 14 an electrode system that comprises the first electrode 20 and at least one second electrode 22a and 22b, wherein either the first electrode 20 or the at least one second electrode 22a and 22b is fixed to the holder 12 in such a way that, by means of a non-zero potential difference applied between the first electrode 20 and the at least one second electrode 22a and 22b, a particular spacing of the first electrode 20 from the at least one second electrode 22a and 22b is variable / is varied. Merely by way of example, in the embodiment of FIG. 1A and 1B, the first electrode 20 is fixed to the holder 12, while the at least one second electrode 22a and 22b can be adjusted in relation to the first electrode 20 by means of the non-zero potential difference. Alternatively, the at least one second electrode 22a and 22b can also be fixed to the holder 12, while the first electrode 20 can be adjusted by means of the non-zero potential difference in relation to the at least one second electrode 22a and 22b. However, if the micromechanical component only comprises the first electrode 20 (and no further electrodes 22a and 22b), the first electrode 20 can also be fixed between the membranes 10a and 10b as a so-called "rigid rear electrode," wherein electrodes can then be integrated on/in the membranes 10a and 10b.

At least the first electrode 20 is configured with continuous recesses 24, in each case in the form of a slot 24. The slots 24 in the first electrode 20 are to be understood to mean continuous recesses 24, which in each case extend along a straight or non-straight slot center longitudinal line 26, i.e., they have their maximum extent parallel to a plane of extension of the first electrode 20 along the straight or non-straight slot center longitudinal line 26. In particular, the slots 24 in the first electrode 20 can in each case have a shape in which a maximum slot length l of the particular slot 24, aligned along the slot center longitudinal line 26, is greater by at least a factor of 3, in particular by a factor of 10, specifically by a factor of 50, than a maximum slot width b, aligned perpendicular to the slot center longitudinal line 26 of the same slot 24 and parallel to the extension plane of the first electrode 20. As an optional addition, the first electrode 20 can have further continuous recesses, in particular further slot-shaped continuous recesses, in addition to the slots 24.

For each of the slots 24 in the first electrode 20, an associated straight line 28 can be defined, which passes through a first endpoint P1 of its slot center longitudinal line 26 lying on an edge of the particular slot 24 and through a second endpoint P2 of its slot center longitudinal line 26 lying on the edge of the particular slot 24. Additionally, for the first electrode 20, a center point M of the first electrode 20 and/or a central axis (not sketched) of the first electrode 20, which intersects the first electrode 20 at its center and with a (substantially) equal total number of slots 24 on each of its two sides, can be defined. Preferably, the slots 24 lie at a particular non-zero spacing from the center point M of the first electrode 20 and/or at a spacing greater than or equal to zero from the central axis of the first electrode 20. Furthermore, a distinction is made between the first endpoint P1 and the second endpoint P2 of each slot 24 in the first electrode 20 in such a way that each first endpoint P1 of the slot center longitudinal line 26 of the slots 24 is closer to the center point M of the first electrode 20 and/or closer to the central axis of the first electrode 20 than the second endpoint P2 of the slot center longitudinal line 26 of the same slot 24.

In addition, the slots 24 in the first electrode 20 are configured such that the associated straight line 28 that can be defined for the particular slot 24 and passes through its first endpoint P1 and its second endpoint P2 extends radially away from the center point M of the first electrode 20 or perpendicularly away from the central axis of the first electrode 20 with a deviation of less than or equal to 20°, preferably less than or equal to 10°, specifically less than or equal to 5°. Thus, the first electrode 20 has a slot design that not only supports sacrificial layer etching through the first electrode 20 but also advantageously contributes to fluidic damping reduction. In this way, damping occurring during a deformation of the membranes 10a and 10b within the internal volume 14 is significantly reduced compared to the previously described prior art.

The reduced damping increases the signal-to-noise ratio when using the micromechanical component described here for a capacitive sensor and/or actuator device, and simultaneously improves the noise performance of the capacitive sensor and/or actuator device. The signal-to-noise ratio can also be understood to mean an SNR (signal-to-noise ratio) value. The SNR value is determined primarily, on the one hand, by a fluidic resistance and, on the other hand, by thermal fluctuations between the first electrode 20 and the gas or gas mixture present in the internal volume 14, which gas or gas mixture must flow past the first electrode 20 in order to cause the membranes 10a and 10b to deform. By means of the advantageous slot design of the first electrode 20, the fluidic resistance is significantly reduced compared to the previously described prior art. In addition, due to the advantageous slot design of the first electrode 20, energy consumption occurring during operation of the capacitive sensor and/or actuator device is reduced and the performance of the capacitive sensor and/or actuator device is increased.

Preferably, the slots 24 configured in the first electrode 20 form a slot pattern that is rotationally symmetrical with respect to the center point M of the first electrode 20 or a slot pattern that is mirror-symmetric with respect to the central axis of the first electrode 20. This also contributes to the reduction of fluidic resistance during deformation of the membranes 10a and 10b.

As an advantageous addition, the first membrane 10a and the second membrane 10b can be connected to one another via support elements 30, wherein the support elements 30 in each case are mechanically coupled to the first membrane surface 16a and to the second membrane surface 16b. Although this is not the case in the embodiment described here, at least two of the support elements 30 can also extend through the same slot 24 in the first electrode 20. Possibly, a through-flow opening 30a can also extend through at least one of the support structures 30 and the membranes 10a and 10b so that an air or gas exchange is possible between a first outer surface of the first membrane 10a directed away from the first membrane surface 16a and a second outer surface of the second membrane 10b directed away from the second membrane surface 16b. Optionally, the first electrode 20 can also be anchored to the holder 12 via at least two anchor structures 32. Preferably in this case, the anchor structures 32 are arranged offset from the slots 24 on the first electrode 20 in order to maintain a tensile stress in the first electrode 20. The tensile stress ensures that the first electrode 20 (substantially) retains its position even with significant deformation of the first and second membranes 10a and 10b. In addition, for each of the anchor structures 32, an anchor-structure straight line (not sketched) can be defined, which passes through a first endpoint of the particular anchor structure 32 anchored at the first electrode 20 and through a second endpoint of the particular anchor structure 32 anchored at the holder 12. If applicable, it is particularly advantageous if each anchor-structure straight line can be mapped by rotation or translation onto each straight line 28 that can be defined for at least one of the slots 24 of the first electrode 20.

If the micromechanical component comprises one of the second electrodes 22a and 22b between the first electrode 20 and the first membrane 10a and the other of the second electrodes 22a and 22b between the first electrode 20 and the second membrane 10b, a spacing of each of the second electrodes 22a and 22b from the first electrode 20 can be less than or equal to 1.5 µm (micrometers). This allows for an advantageously high capacitance measurement signal. Optionally, the second electrodes 22a and 22b can be spaced apart from the adjacent membrane 10a or 10b and, if necessary, mechanically coupled to it. By spacing the second electrodes 22a and 22b away from the respective adjacent membrane 10a or 10b, a fluidic relief space is created between them, which can make an additional contribution to reducing damping.

If the micromechanical component comprises not only the first electrode 20 but also the at least one second electrode 22a and 22b, the at least one second electrode 22a and 22b can also be configured with continuous recesses 34, in each case in the form of a slot 34 extending along a straight or non-straight slot center longitudinal line 36. For each of the slots 34 in the at least one second electrode 22a and 22b, an associated straight line 38 can be defined, which passes through a first endpoint P3 of its slot center longitudinal line 36 lying on an edge of the particular slot 34 and through a second endpoint P4 of its slot center longitudinal line 36 lying on the edge of the particular slot 34. For the at least one second electrode 22a and 22b as well, a center point MP of the particular second electrode 22a or 22b and/or a central axis (not sketched) of the particular second electrode 22a or 22b, which intersects the particular second electrode 22a or 22b at its center and with a substantially equal total number of slots 34 on each of its two sides, can also be defined.

Preferably, the slots 34 in the at least one second electrode 22a and 22b are in this case configured such that the straight line 38 that can be defined for the particular slot 34 and passes through the first endpoint P3 of its slot center longitudinal line 36 and through the second endpoint P4 of its slot center longitudinal line 36 extends radially away from the center point MP of the particular second electrode 22a or 22b or perpendicularly away from the central axis of the particular second electrode 22a or 22b, which intersects the particular second electrode 22a or 22b at its center, with a deviation of less than or equal to 20°, preferably less than or equal to 10°, specifically less than or equal to 5°. Thus, the at least one second electrode 22a and 22b can also be configured with the advantageous slot design already explained above, analogous to that of the first electrode 20. The advantageous slot design of the at least one second electrode 22a and 22b can also contribute to reducing damping occurring during the deformation of the membranes 10a and 10b. With respect to the advantageous properties of the slots 34 configured in the at least one second electrode 22a and 22b, reference is made to the preceding and following description of the slots 24 of the first electrode 20.

As also shown in the illustration, the slots 34 in the at least one second electrode 22a and 22b can be configured with an offset 40 in relation to the slots 24 in the first electrode 20. The offset 40 can be a rotational offset 40 or a translational offset (not shown). By means of the offset 40, the path length for gas molecules from the gap between the first and second electrodes through the slots 24 and 34 is shortest so that the resulting damping is lowest.

In the embodiment of FIG. 1A to 1D, all slots 24 in the first electrode 20 extend radially away/outward from the center point M. In FIG. 1B, the dashed lines 42 show a projection of the slots 34 configured in the at least one second electrode 22a and 22b onto the first electrode 20 in order to illustrate the rotational offset 40 of the slots 34 in the at least one second electrode 22a and 22b in relation to the slots 24 in the first electrode 20.

Preferably, a negative pressure prevails in the internal volume 14, in particular a negative pressure of less than or equal to 10 mbar (millibar). The micromechanical component therefore operates in the molecular flow regime (and not in the continuum flow regime, as would be the case at normal pressure in the internal volume 14), wherein, due to the advantageous slot design of the first electrode 20 and, if applicable, the at least one second electrode 22a and 22b, the damping by the residual gas is significantly reduced and thus the noise is reduced.

Preferably, a particular spacing between two adjacent slots 24 of the first electrode 20 is in a range of values between 2 µm (micrometers) and 12 µm (micrometers). This ensures a relatively low fluidic resistance during deformation of the membranes 10a and 10b.

In the coordinate system of FIG. 1D, the abscissa indicates an initial tensile stress σ (in mega-pascals) occurring in a first electrode 20, while the ordinate shows a sensitivity S of the particular micromechanical component (in nanometers/pascals). The graphs g4, g8 and g10 represent the data of micromechanical components according to the embodiment shown in FIG. 1A to 1C, wherein the particular spacing between two adjacent slots 24 of the first electrode 20 is equal to 4 µm (micrometers) for the graph g4, equal to 8 µm (micrometers) for the graph g8 and equal to 10 µm (micrometers) for the graph g10. In contrast, the graph g0 shows the data of a conventional component without slots in its first electrode 20. The graphs g0-4 and g0-8 provide data. It can be seen from the coordinate system of FIG. 1D that the advantageous slot design of the embodiment described here also remedies a conventional dependence of the sensitivity S on the initial stress σ of the first electrode 20. This significantly simplifies manufacturing of the parts of the micromechanical component and leads to a higher yield.

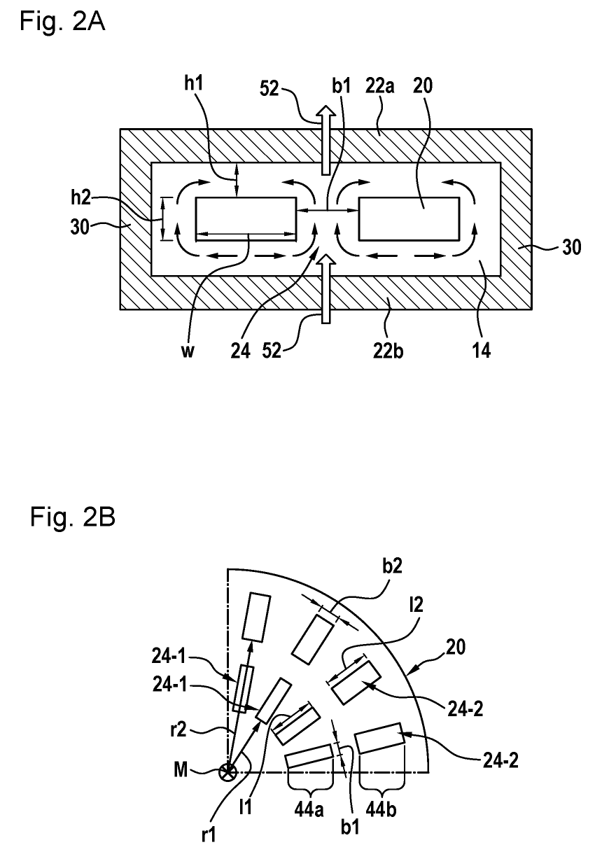

FIG. 2A and 2B are schematic partial representations of a second embodiment of the micromechanical component.

In the micromechanical component shown schematically in FIG. 2A and 2B, the slots 24 in the first electrode 20 are configured such that the straight lines 28 passing through the first endpoint P1 of the slot center longitudinal line 26 of the particular slot 24 and through the second endpoint P2 of the slot center longitudinal line 26 of the same slot 24 extend radially away from the center point M of the first electrode 20 with a deviation of less than or equal to 20°, preferably less than or equal to 10°, specifically less than or equal to 5°. As the slots 24, at least first slots 24-1 and second slots 24-2 are formed in the first electrode 20 such that the first endpoints P1 of the slot center longitudinal lines 26 of the first slots 24-1 lie on a first circular path 44a having a first radius r1 about the center point M of the first electrode 20, and the first endpoints P1 of the slot center longitudinal lines 26 of the second slots 24-2 lie on a second circular path 44b having a second radius r2 about the center point M of the first electrode 20, wherein the second radius is greater than the first radius. Thus, the slots can be formed in at least two concentric rings around the center point M of the first electrode 20.

The first slots 24-1 and the second slots 24-2 can have a particular maximum slot length l1 and l2 radially away from the center point M of the first electrode 20 and a particular maximum slot width b1 and b2 perpendicular to their particular maximum slot length l1 or l2. Preferably the maximum slot length l1 or l2 lies in a range between 1 µm (micrometers) and 500 µm (micrometers), specifically between 5 µm (micrometers) and 100 µm (micrometers), preferably between 10 µm (micrometers) and 30 µm (micrometers). The maximum slot width b1 or b2 can lie in a range between 0.2 µm (micrometers) and 20 µm (micrometers), preferably between 0.5 µm (micrometers) and 5 µm (micrometers), preferably between 0.5 µm (micrometers) and 2 µm (micrometers).

The first slots 24-1 preferably have an equal first maximum slot length l1 and an equal first maximum slot width b1, while the second slots 24-2 have an equal second maximum slot length l2 and an equal second maximum slot width b2. It can be advantageous if the first maximum slot length l1 differs from the second maximum slot length l2 and/or if the first maximum slot width b1 differs from the second maximum slot width b2. Alternatively or additionally, the total number of first slots 24-1 can also differ from the total number of second slots 24-2.

Preferably, the ratio of the sum of the maximum slot widths b1 or b2 of all slots 24-1 or 24-2 on the same circular path 44a or 44b divided by a corresponding circumference length 2πr1² or 2πr2² is between 1% and 50%, in particular between 1% and 20%. This ratio represents a particularly good compromise between a desired reduction in damping and an undesired loss of capacitance through the slots 24.

The particular spacing h1 of the first electrode 20 from the at least one second electrode 22a and 22b is between 0.1 µm (micrometers) and 10 µm (micrometers), preferably between 0.5 µm (micrometers) and 3 µm (micrometers). A height h2 of the slots 24 is equal to a height of the first electrode 20, e.g., between 0.1 µm (micrometers) and 30 µm (micrometers), specifically between 1 µm (micrometers) and 3 µm (micrometers). For the spacing w between two adjacent slots 24, values between 1 µm (micrometer) and 200 µm (micrometer), specifically between 2 µm (micrometer) and 10 µm (micrometer), are preferred.

With respect to further features and properties of the micromechanical component of FIG. 2A and 2B and its advantages, reference is made to the description of the preceding embodiment of FIG. 1A to 1D.

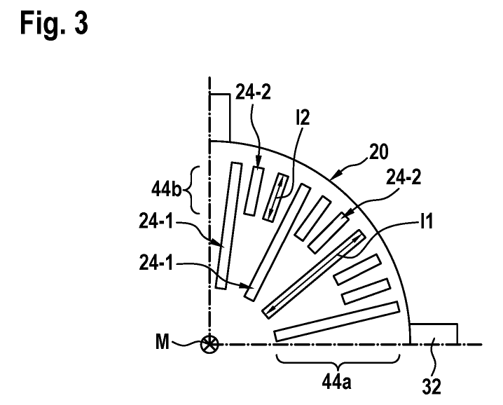

FIG. 3 is a schematic partial representation of a third embodiment of the micromechanical component.

As shown in FIG. 3, the first maximum slot length l1 of the first slots 24-1 and the second maximum slot length l2 of the second slots 24-2 can also differ from one another in such a way that the first slots 24-1 "dip" into the ring 44b formed by the second slots 24-2. If applicable, the first maximum slot length l1 is greater than a difference of the second radius r2 minus the first radius r1.

With respect to further features and properties of the micromechanical component of FIG. 3 and its advantages, reference is made to the description of the preceding embodiment of FIG. 1A-2B.

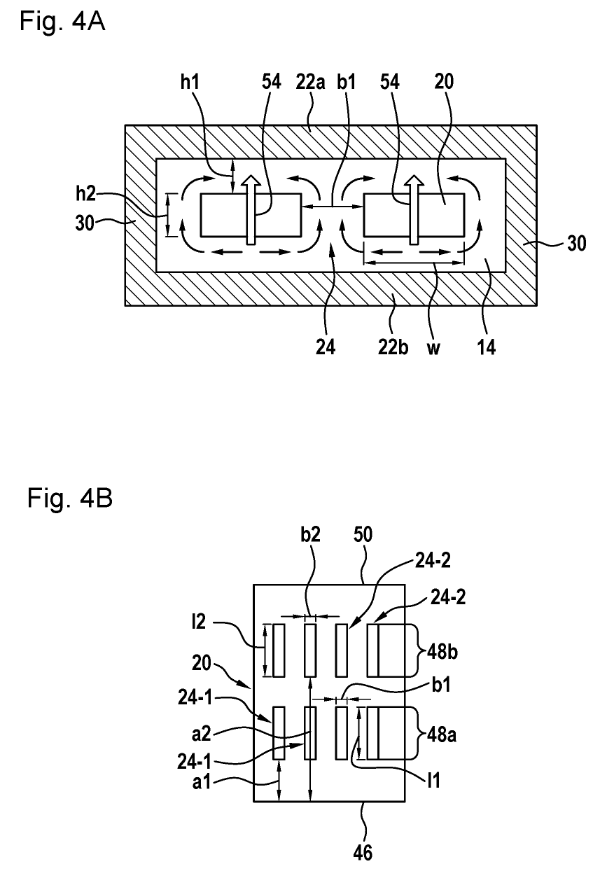

FIG. 4A and 4B are schematic partial representations of a fourth embodiment of the micromechanical component.

In contrast to the embodiments explained above, in the micromechanical component of FIG. 4A and 4B, the slots 24 in the first electrode 20 are configured such that the straight lines 28 passing through the first endpoint P1 of the slot center longitudinal line 26 of the particular slot 24 and through the second endpoint P2 of the slot center longitudinal line 26 of the same slot 24 extend perpendicularly away from the central axis 46 of the first electrode 20 with a deviation of less than or equal to 20°, preferably less than or equal to 10°, specifically less than or equal to 5°. As the slots 24, at least first slots 24-1 and second slots 24-2 are configured in the first electrode 20 such that the first endpoints P1 of the slot center longitudinal lines 26 of the first slots 24-1 lie on two straight lines running parallel to the central axis 46 of the first electrode 20 at an equal first spacing a1 from the central axis 46 of the first electrode 20, and the first endpoints P1 of the slot center longitudinal lines 26 of the second slots 24-2 lie on two further straight lines running parallel to the central axis 46 of the first electrode 20 at an equal second spacing a2 from the central axis 46 of the first electrode 20, wherein the second spacing a2 is greater than the first spacing a1. The first slots 24-1 can thus be described as two slot strips 48a running parallel and equidistant to the central axis 46 of the first electrode 20. Accordingly, the second slots 24-2 can also be described as two further slot strips 48b running parallel and equidistant to the central axis 46 of the first electrode 20. Advantageous ranges of values for the particular maximum slot lengths l1 and l2 and particular maximum slot widths b1 and b2 of the slots 24, the particular spacing h1 of the first electrode 20 from the at least one second electrode 22a and 22b, the height h2 of the slots 24 and the spacing w between two adjacent slots 24 are already given above.

Preferably, the first slots 24-1 have an equal first maximum slot length l1 perpendicular to the central axis 46 of the first electrode 20 and an equal first maximum slot width b1 parallel to the central axis 46 of the first electrode 20. Accordingly, it is preferred if the second slots 24-2 also have an equal second maximum slot length l2 perpendicular to the central axis 46 of the first electrode 46 and an equal second maximum slot width b2 parallel to the central axis 46 of the first electrode 20. Preferably, however, the first maximum slot length l1 can differ from the second maximum slot length l2 and/or the first maximum slot width b1 can differ from the second maximum slot width b2. Alternatively or additionally, the total number of first slots 24-1 can also differ from the total number of second slots 24-2. Additionally, it is advantageous if the ratio of a sum of the maximum slot widths b1 or b2 of all slots 24-1 or 24-2 on the same straight line running parallel to the central axis 46 of the first electrode 20 divided by an edge length of an edge 50 running parallel to the central axis 46 of the first electrode 20 is between 0.5% and 50%, in particular between 1% and 20%. This as well represents a good compromise between a desired reduction in damping and an undesired loss of capacitance through the slots 24.

With respect to further features and properties of the micromechanical component of FIG. 4A and 4B and its advantages, reference is made to the description of the preceding embodiments of FIGS. 1A-1D, 2A, 2B, and 3.

As schematically shown in FIG. 2A and 4A by means of arrows 52 and 54, when the first electrode 20 is arranged between two second electrodes 22a and 22b, either the second electrodes 22a and 22b can be mechanically attached to the holder 12 in an adjustable manner, while the first electrode 20 is fixed (non-adjustably) to the holder 12 (see FIG. 2A), or the second electrodes 22a and 22b can be fixed (non-adjustably) to the holder 12, while the first electrode 20 is mechanically attached to the holder 12 in an adjustable manner in relation to each second electrode 22a and 22b (see FIG. 4A).

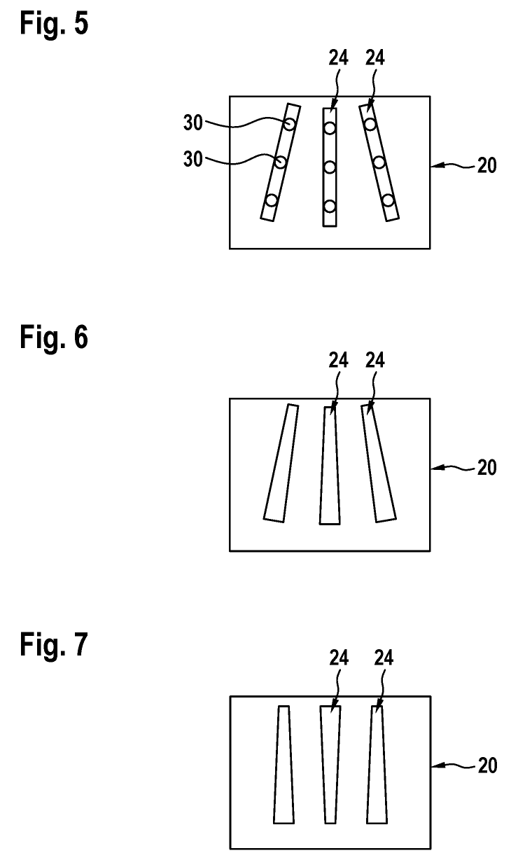

FIG. 5 to 9 are schematic partial representations of further embodiments of the micromechanical component.

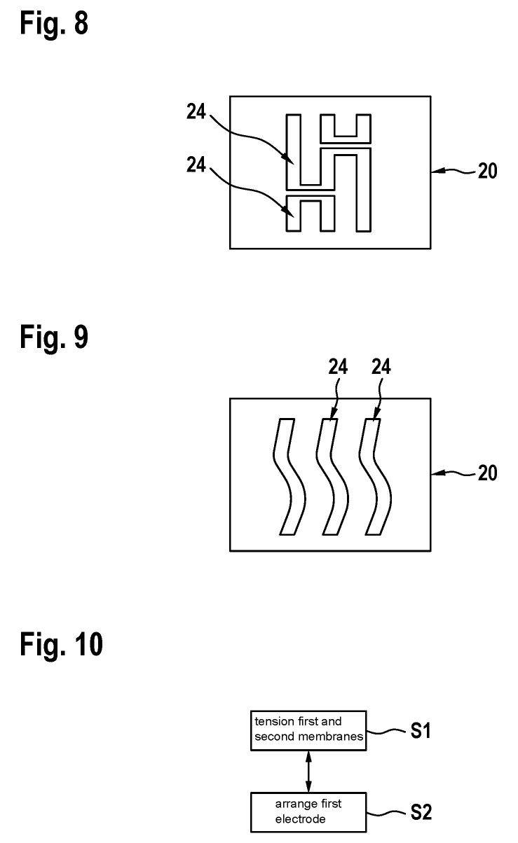

As shown schematically in FIG. 5 to 9, at least some of the slots 24 can be configured to be rectangular (FIG. 5), trapezoidal (FIG. 6 and 7), meandering (FIG. 8) and/or S-shaped (FIG. 9). Thus, a large number of different design variants for the shape of the slots 24 in a cross-sectional plane aligned parallel to the maximum surface of the first electrode 20 is possible.

It can also be seen in FIG. 5 and 6 that the rectangular shape and/or the trapezoidal shape of the slots 24 can be well combined with their radial alignment in relation to a center point M (not shown) of the first electrode 20. In the trapezoidal shape of the slots 24 shown in FIG. 6, the shorter side surfaces are aligned toward the center point M of the first electrode 20. This ensures a constant spacing between two adjacent slots 24 of a ring 44a or 44b.

However, as shown schematically in FIG. 7, the short edges and the long edges of the slots can also be configured alternately on the first electrode 20. The meandering shape of the slots 24 shown in FIG. 8 can be achieved by adding rectangular slots with additional transverse slots. The S-shaped slots 24 of FIG. 9 also allow for a constant spacing between two adjacent slots 24.

With respect to further features and properties of the micromechanical component of FIG. 5 to 9 and its advantages, reference is made to the description of the preceding embodiments of FIGS. 1A to 3B.

All micromechanical components described above can be advantageously used for a capacitive sensor and/or actuator device. The capacitive sensor and/or actuator device can, for example, be a pressure sensor, in particular a capacitive relative pressure sensor, a microphone and/or a loudspeaker.

In all micromechanical components described above, the slot design configured at least in its first electrode 20 reduces the damping occurring during operation of the capacitive sensor and/or actuator device configured therewith, which is why the particular capacitive sensor and/or actuator device is particularly efficient and has a particularly high signal-to-noise ratio. Despite the minimal damping during operation of the particular capacitive sensor and/or actuator device equipped with it, its first electrode 20 has maximum stability, which is why the particular micromechanical component has an advantageous robustness against damage or aging effects.

At the same time, each of the micromechanical components described above has an advantageous separation of the functions of damping and preload properties because the total number of slots 24 of the particular first electrode 20 influences the damping occurring during operation of the capacitive sensor and/or actuator device equipped with it more than the voltage change occurring simultaneously. Due to the dynamic pressure changes occurring during operation of the particular capacitive sensor and/or actuator device, an advantageously high SNR ratio is also ensured.

FIG. 10 is a flowchart to explain one embodiment of the production method for a micromechanical component for a capacitive sensor and/or actuator device.

In a method step S1 of the production method described here, a deformable first membrane and a deformable second membrane are tensioned on and/or in a holder of the later micromechanical component in such a way that an internal volume is bounded on its first side by a first membrane surface of the first membrane and on its second side, which is directed away from the first side, by a second membrane surface of the second membrane. A method step S2 is also executed before, after or simultaneously with method step S1. In method step S2, at least one first electrode is arranged in the internal volume.

In addition, in method step S2, the first electrode is formed with continuous recesses, in each case in the form of a slot extending along a straight or non-straight slot center longitudinal line. In addition, the slots in the first electrode are configured such that a straight line that can be defined for the particular slot and passes through a first endpoint of its slot center longitudinal line lying on an edge of the particular slot and through a second endpoint of its slot center longitudinal line lying on the edge of the particular slot extends radially away from a center point of the first electrode with a deviation of less than or equal to 20° or extends perpendicularly away from a central axis of the first electrode, which intersects the first electrode at its center and with a (substantially) equal total number of slots on each of its two sides, with a deviation of less than or equal to 20°. Thus, a micromechanical component produced using the production method described here also has the advantages explained above. Optionally, further features of the micromechanical components described above can also be implemented when carrying out the production method.

What is claimed is:

1. A micromechanical component for a capacitive sensor and/or actuator device, comprising:
a deformable first membrane and a deformable second membrane, which are tensioned on and/or in a holder of the micromechanical component in such a way that an internal volume is bounded on a first side by a first membrane surface of the first membrane and on a second side, which is directed away from the first side, by a second membrane surface of the second membrane; and
at least one first electrode arranged in the internal volume, wherein the first electrode includes continuous recesses, each of the recesses being a slot extending along a straight or non-straight slot center longitudinal line of the slot;
wherein the slots in the first electrode are configured such that a straight line that can be defined for each slot of the slots and passes through a first endpoint of the slot center longitudinal line of the slot lying on an edge of the slot and through a second endpoint of the slot center longitudinal line of the slot lying on the edge of the slot: (i) extends radially away from a center point of the first electrode with a deviation of less than or equal to 20° or (ii) extends perpendicularly away from a central axis of the first electrode, which intersects the first electrode at a center of the first electrode and with an equal total number of the slots on each of two sides of the first electrode, with a deviation of less than or equal to 20°.

2. The micromechanical component according to claim 1, wherein the slots in the first electrode are configured such that the straight lines passing through the first endpoint of the slot center longitudinal line of each slot of the slots and through the second endpoint of the slot center longitudinal line of the same slot extend radially away from the center point of the first electrode with a deviation of less than or equal to 20°, wherein each first endpoint of the slot center longitudinal lines of the slots is closer to the center point of the first electrode than the second endpoint of the slot center longitudinal line of the same slot, and wherein the slots include first slots and second slots, wherein, at least the first slots and the second slots in the first electrode are configured such that the first endpoints of the slot center longitudinal lines of the first slots lie on a first circular path having a first radius about the center point of the first electrode, and the first endpoints of the slot center longitudinal lines of the second slots lie on a second circular path having a second radius, greater than the first radius, about the center point of the first electrode.

3. The micromechanical component according to claim 2, wherein the first slots have an equal first maximum slot length radially away from the center point of the first electrode and an equal first maximum slot width perpendicular to a first maximum slot length of the first slots, and the second slots have an equal second maximum slot length radially away from the center point of the first electrode and an equal second maximum slot width perpendicular to a second maximum slot length of the second slots, and wherein the first maximum slot length differs from the second maximum slot length and/or the first maximum slot width differs from the second maximum slot width.

4. The micromechanical component according to claim 1, wherein the slots in the first electrode are configured such that the straight lines passing through the first endpoint of the slot center longitudinal line of each of the slots and through the second endpoint of the slot center longitudinal line of the same slot extend perpendicularly away from the central axis of the first electrode with a deviation of less than or equal to 20°, wherein each first endpoint of the slot center longitudinal lines of the slots is closer to the central axis of the first electrode than the second endpoint of the slot center longitudinal line of the same slot, and wherein the slots include first slots and second slots, at least the first slots and the second slots in the first electrode are configured such that the first endpoints of the slot center longitudinal lines of the first slots lie on two straight lines running parallel to the central axis of the first electrode at an equal first spacing to the central axis of the first electrode and the first endpoints of the slot center longitudinal lines of the second slots lie on two further straight lines running parallel to the central axis of the first electrode at an equal second spacing, greater than the first spacing, to the central axis of the first electrode.

5. The micromechanical component according to claim 4, wherein the first slots have an equal first maximum slot length perpendicular to the central axis of the first electrode and an equal first maximum slot width parallel to the central axis of the first electrode, and the second slots have an equal second maximum slot length perpendicular to the central axis of the first electrode and an equal second maximum slot width parallel to the central axis of the first electrode, and wherein the first maximum slot length differs from the second maximum slot length and/or the first maximum slot width differs from the second maximum slot width.

6. The micromechanical component according to claim 1, wherein at least some of the slots are trapezoidal and/or meandering and/or S-shaped.

7. The micromechanical component according to claim 1, wherein the first membrane is mechanically connected to the second membrane via support elements, wherein each of the support elements is mechanically coupled to the first membrane surface and to the second membrane surface, and wherein at least two of the support elements extend through the same slot in the first electrode.

8. The micromechanical component according to claim 1, wherein each spacing between two adjacent slots of the slots of the first electrode lies in a range of values between 2 µm and 12 µm.

9. The micromechanical component according to claim 1, wherein an electrode system that includes the first electrode and at least one second electrode is arranged in the internal volume, and wherein the first electrode or the at least one second electrode is fixed to the holder in such a way that a spacing of the first electrode from the at least one second electrode can be varied using a non-zero potential difference applied between the first electrode and the at least one second electrode.

10. The micromechanical component according to claim 9, wherein the at least one second electrode includes continuous recesses, each of the recesses in the at least one second electrode being a slot extending along a straight or non-straight slot center longitudinal line of the slot, wherein each slot of the slots in the at least one second electrode are configured such that a straight line that can be defined for the slot and passes through a first endpoint of the slot center longitudinal line lying of the slot on an edge of the slot and through a second endpoint of the slot center longitudinal line of the slot lying on the edge of the slot: (i) extends radially away from a center point of the second electrode with a deviation of less than or equal to 20° or (ii) extends perpendicularly away from a central axis of the second electrode, which intersects the at least one second electrode at its center, with a deviation of less than or equal to 20°, and wherein the slots in the at least one second electrode are configured with an offset in relation to the slots in the first electrode.

11. The micromechanical component according to claim 1, wherein each slot of the slots in the first electrode are configured such that the straight line passing through the first endpoint of the slot center longitudinal line of the particular slot and through the second endpoint of the slot center longitudinal line of the same slot extends: (i) radially away from the center point of the first electrode with a deviation of less than or equal to 10° or (ii) perpendicularly away from the central axis of the first electrode with a deviation of less than or equal to 10°.

12. The micromechanical component according to claim 1, wherein each slot of the slots in the first electrode are configured such that the straight line passing through the first endpoint of the slot center longitudinal line of the slot and through the second endpoint of the slot center longitudinal line of the same slot extends: (i) radially away from the center point of the first electrode with a deviation of less than or equal to 5° or (ii) perpendicularly away from the central axis of the first electrode with a deviation of less than or equal to 5°.

13. The micromechanical component according to claim 1, wherein the first electrode is anchored to the holder using at least two anchor structures in such a way that an anchor-structure straight line that can be defined for each anchor structure of the anchor structures and passes through a first endpoint of the anchor structure anchored to the first electrode and through a second endpoint of the anchor structure anchored to the holder can be mapped by rotation or translation onto each straight line that can be defined for at least one of the slots of the first electrode.

14. A capacitive sensor and/or actuator device, comprising:
a micromechanical component including:
a deformable first membrane and a deformable second membrane, which are tensioned on and/or in a holder of the micromechanical component in such a way that an internal volume is bounded on a first side by a first membrane surface of the first membrane and on a second side, which is directed away from the first side, by a second membrane surface of the second membrane, and
at least one first electrode arranged in the internal volume, wherein the first electrode includes continuous recesses, each of the recesses being a slot extending along a straight or non-straight slot center longitudinal line of the slot,
wherein the slots in the first electrode are configured such that a straight line that can be defined for each slot of the slots and passes through a first endpoint of the slot center longitudinal line of the slot lying on an edge of the slot and through a second endpoint of the slot center longitudinal line of the slot lying on the edge of the slot: (i) extends radially away from a center point of the first electrode with a deviation of less than or equal to 20° or (ii) extends perpendicularly away from a central axis of the first electrode, which intersects the first electrode at a center of the first electrode and with an equal total number of the slots on each of two sides of the first electrode, with a deviation of less than or equal to 20°.

15. A production method for a micromechanical component for a capacitive sensor and/or actuator device, comprising the following steps:
tensioning a deformable first membrane and a deformable second membrane on and/or in a holder of the produced micromechanical component in such a way that an internal volume is bounded on a first side by a first membrane surface of the first membrane and on a second side, which is directed away from the first side, by a second membrane surface of the second membrane; and
arranging at least one first electrode in the internal volume, wherein the first electrode is configured with continuous recesses, each recess of the recesses being a slot extending along a straight or non-straight slot center longitudinal line of the slot;
wherein each slot of the slots in the first electrode are configured such that a straight line that can be defined for the slot and passes through a first endpoint of the slot center longitudinal line of the slot lying on an edge of the slot and through a second endpoint of the slot center longitudinal line of the slot lying on the edge of the slot: (i) extends radially away from a center point of the first electrode with a deviation of less than or equal to 20° or (ii) extends perpendicularly away from a central axis of the first electrode, which intersects the first electrode at a center of the first electrode and with an equal total number of the slots on each of two sides of the first electrode, with a deviation of less than or equal to 20°.
